(19) United States
(12) Patent Application Publication
(10) Pub. No.: US 2026/0277092 A1
(43) Pub. Date: Sep. 17, 2026

(54) REFLECTIVE MASK BLANK, REFLECTIVE MASK, REFLECTIVE MASK BLANK MANUFACTURING METHOD, AND REFLECTIVE MASK MANUFACTURING METHOD

(71) Applicant: AGC INC., Tokyo (JP)

(72) Inventors: Daijiro AKAGI, Tokyo (JP); Takeshi TOMIZAWA, Tokyo (JP)

(73) Assignee: AGC INC., Tokyo (JP)

(21) Appl. No.: 19/676,022

(22) Filed: May 13, 2026

Related U.S. Application Data
(63) Continuation of application No. PCT/JP2024/040091, filed on Nov. 12, 2024.

(30) Foreign Application Priority Data
Nov. 29, 2023 (JP) 2023-201163

(51) Int. Cl. G03F 1/24

(52) U.S. Cl. CPC G03F 1/24

(57) ABSTRACT

This reflective mask blank has, in the following order, a substrate, a multilayer reflective film that reflects EUV light, and an absorbing film that absorbs EUV light, and further has a conductive film on a side opposite to the multilayer reflective film from the substrate from as a reference. The conductive film has a Young's modulus of 250 GPa or less as measured by the nanoindenter.

The present application is a continuation of PCT/JP2024/040091, filed on Nov. 12, 2024, the entire contents of which are incorporated herein by reference.

### TECHNICAL FIELD

The present invention relates to a reflective mask blank, a reflective mask, a reflective mask blank manufacturing method, and a reflective mask manufacturing method.

### BACKGROUND ART

In recent years, with the miniaturization of semiconductor devices, extreme ultra-violet lithography (EUVL), which is an exposure technology using extreme ultraviolet (EUV) rays, has been developed. EUV includes soft X-rays and vacuum ultraviolet rays, and specifically indicates light with wavelengths of approximately 0.2 nm to 100 nm. Currently, EUV light with a wavelength of approximately 13.5 nm is the primary focus of research.

EUVL uses a reflective mask. A reflective mask has, for example, a substrate, a multilayer reflective film, and an absorbing film, in this order. The multilayer reflective film reflects EUV light. The absorbing film absorbs EUV light. The absorbing film may not only absorb EUV light, but also shift a phase of the EUV light. That is, the absorbing film may be a phase shift film. In EUVL, an opening pattern of the absorbing film is transferred to a target substrate such as a semiconductor substrate. Transferring includes transferring the pattern at a reduced size.

The reflective mask has a conductive film on a side opposite to the multilayer reflective film from the substrate as a reference. The conductive film is used, for example, to attach the reflective mask to an electrostatic chuck in an exposure device. A conductive film of a reflective mask described in Patent Document 1 has a static friction coefficient of 0.25 or more measured in air. It is stated that a static friction coefficient of 0.25 or more can suppress positional deviation of the reflective mask even when an electrostatic chuck moves at high speed.

### CITATION LIST

### Patent Document

Patent Document 1: International Publication No. WO 2016/204051

### SUMMARY OF INVENTION

### Technical Problem

An electrostatic chuck of an exposure device repeatedly attaches and releases a reflective mask for purposes such as maintenance or replacement of the reflective mask. In this case, the electrostatic chuck wears. As a result, particles may be generated. The particles are caught between the electrostatic chuck and the reflective mask and deform the reflective mask. As a result, EUVL transfer accuracy may deteriorate.

One aspect of the present disclosure provides a technology for suppressing wear of an electrostatic chuck that electrostatically attaches a reflective mask.

### Solution to Problem

A reflective mask blank according to one aspect of the present disclosure has a substrate, a multilayer reflective film configured to reflect EUV light, and an absorbing film configured to absorb EUV light, in this order, and has a conductive film on a side opposite to the multilayer reflective film from the substrate as a reference. The conductive film has a Young's modulus of 250 GPa or less as measured with a nanoindenter.

### Advantageous Effects of Invention

According to one aspect of the present disclosure, wear of an electrostatic chuck that electrostatically attaches a reflective mask can be suppressed.

### BRIEF DESCRIPTION OF DRAWINGS

FIG. 1 is a cross-sectional view showing a reflective mask blank according to one embodiment.

FIG. 2 is a flowchart showing a manufacturing method of a reflective mask blank according to one embodiment.

FIG. 3 is a cross-sectional view showing a reflective mask according to one embodiment.

FIG. 4 is a flowchart showing a manufacturing method of a reflective mask according to one embodiment.

FIG. 5A is a cross-sectional view showing an example of S201.

FIG. 5B is a cross-sectional view showing an example of S202.

FIG. 5C is a cross-sectional view showing an example of S203.

FIG. 6 is a cross-sectional view showing an example of EUV light reflected by the reflective mask of FIG. 3.

FIG. 7 is a cross-sectional view showing an example of a reflective mask and an electrostatic chuck.

FIG. 8 is a cross-sectional view showing another example of a reflective mask and an electrostatic chuck.

FIG. 9 is a cross-sectional view showing an example of arrangement of electrodes used for measuring contact resistance.

FIG. 10 is a diagram showing an example of a relationship between resistance, inter-electrode distance, and contact resistance.

### DESCRIPTION OF EMBODIMENTS

Aspects for implementing the present disclosure will be described below with reference to the drawings. Identical or corresponding configurations in each figure will be denoted by the same reference signs, and their description may be omitted. In the specification, the term “to” indicating a numerical range indicates that numerical values before and after it are included as lower and upper limits. Numerical ranges include rounded ranges.

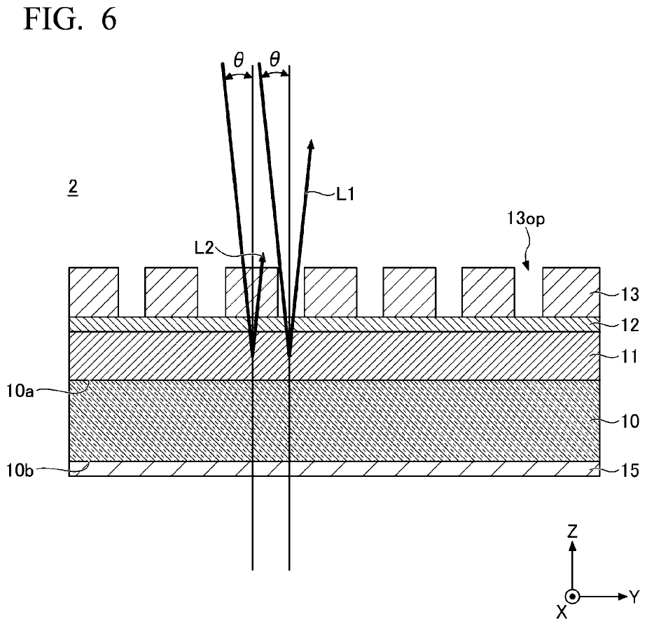

In each figure, X axis, Y axis, and Z axis directions are orthogonal to each other. The Z axis direction is a direction perpendicular to a first major surface 10a of a substrate 10. The X axis direction is a direction perpendicular to an incidence plane of EUV light (a plane including incident and reflected light rays). As shown in FIG. 6, the incident light rays are tilted toward a positive Y axis as they move in a negative Z axis direction, and the reflected light rays are tilted toward the positive Y axis as they move in a positive Z axis direction.

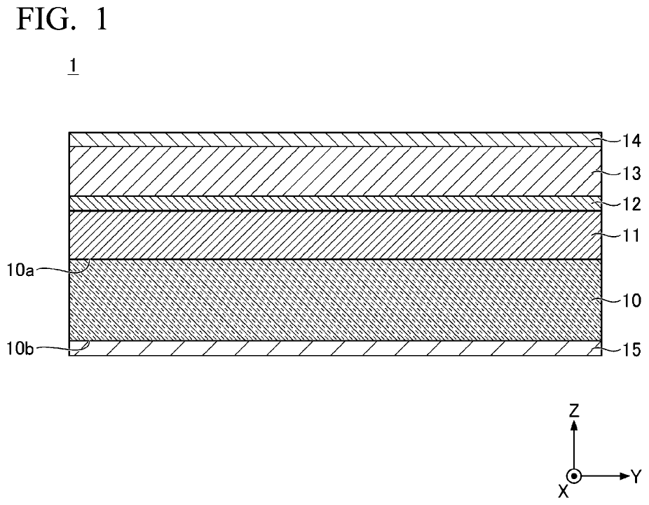

A reflective mask blank 1 according to one embodiment will be described with reference to FIG. 1. The reflective mask blank 1 has, for example, the substrate 10, a multilayer reflective film 11, a protective film 12, an absorbing film 13, and a hard mask film 14, in this order. The multilayer reflective film 11, the protective film 12, the absorbing film 13, and the hard mask film 14 are formed, in this order, on the first major surface 10a of the substrate 10. The multilayer reflective film 11 reflects EUV light. The protective film 12 protects the multilayer reflective film 11 from a first etching gas during processing of the absorbing film 13. The absorbing film 13 absorbs EUV light. The absorbing film 13 may not only absorb EUV light, but also shift a phase of the EUV light. That is, the absorbing film 13 may be a phase shift film. The hard mask film 14 protects a part of the absorbing film 13 from the first etching gas during processing of the absorbing film 13.

The reflective mask blank 1 has a conductive film 15 on a side opposite to the multilayer reflective film 11 from the substrate 10 as a reference. That is, the reflective mask blank 1 may have the conductive film 15, the substrate 10, the multilayer reflective film 11, the protective film 12, the absorbing film 13, and the hard mask film 14, in this order. The conductive film 15 is formed on a second major surface 10b of the substrate 10. The second major surface 10b is a surface facing opposite to the first major surface 10a. The conductive film 15 is used to attach a reflective mask 2 to an electrostatic chuck of an exposure device.

The reflective mask blank 1 may further have a functional film not shown in FIG. 1. For example, the reflective mask blank 1 may have a diffusion barrier film (not shown) between the multilayer reflective film 11 and the protective film 12. The diffusion barrier film suppresses the diffusion of metal elements contained in the protective film 12 into the multilayer reflective film 11.

Although not shown, the reflective mask blank 1 may have a buffer film between the protective film 12 and the absorbing film 13. The buffer film protects the protective film 12 from the first etching gas that forms an opening pattern 13op in the absorbing film 13. The buffer film is etched more slowly than the absorbing film 13. Unlike the protective film 12, the buffer film ultimately has an opening pattern identical to the opening pattern 13op in the absorbing film 13.

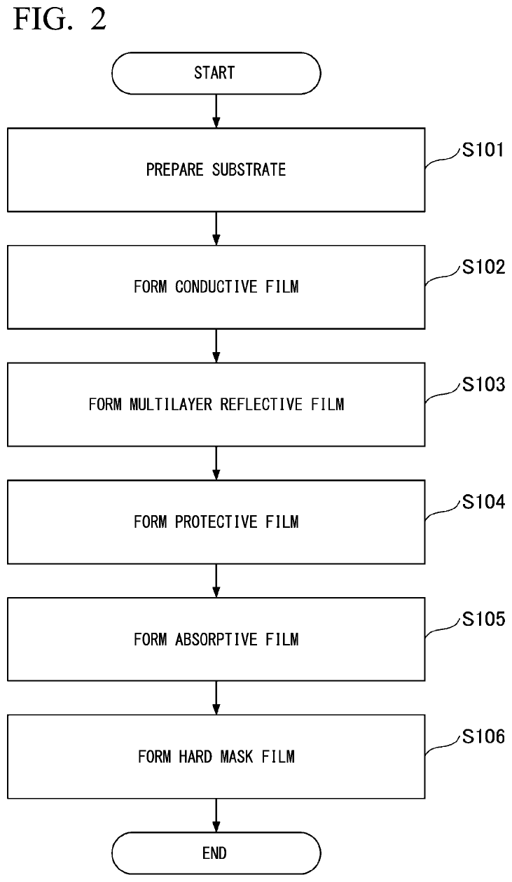

Next, with reference to FIG. 2, a manufacturing method of the reflective mask blank 1 according to one embodiment will be described. The manufacturing method of the reflective mask blank 1 has, for example, steps S101 to S106 shown in FIG. 2. In step S101, the substrate 10 is prepared. In step S102, the conductive film 15 is formed on the second major surface 10b of the substrate 10. In step S103, the multilayer reflective film 11 is formed on the first major surface 10a of the substrate 10. In step S104, the protective film 12 is formed on the multilayer reflective film 11. In step S105, the absorbing film 13 is formed on the protective film 12. In step S106, the hard mask film 14 is formed on the absorbing film 13.

Also, the order of steps S101 to S106 is not limited to the order shown in FIG. 2. For example, the order of step S102 and steps S103 to S106 may be reversed. Further, the manufacturing method of the reflective mask blank 1 does not necessarily have to include all of steps S101 to S106. The manufacturing method of the reflective mask blank 1 may further have a step of forming a functional film not shown in FIG. 2.

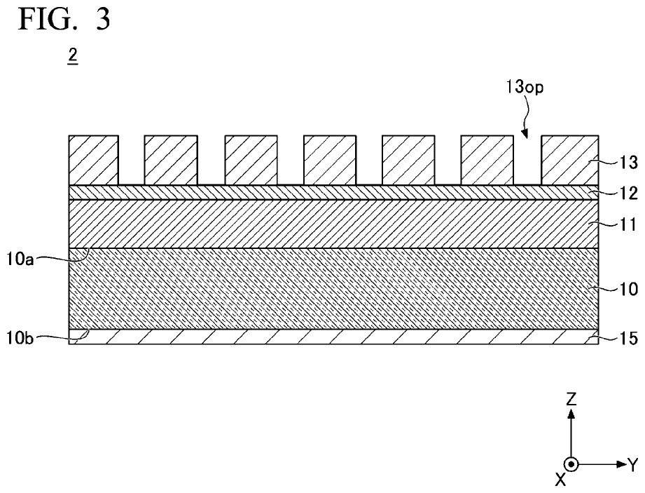

Next, with reference to FIG. 3, the reflective mask 2 according to one embodiment will be described. The reflective mask 2 includes, for example, the reflective mask blank 1 shown in FIG. 1, and includes the opening pattern 13op in the absorbing film 13. In EUVL, the opening pattern 13op of the absorbing film 13 is transferred to a target substrate such as a semiconductor substrate. Transferring includes reduction transfer. Also, the hard mask film 14 shown in FIG. 1 is not included in the reflective mask 2.

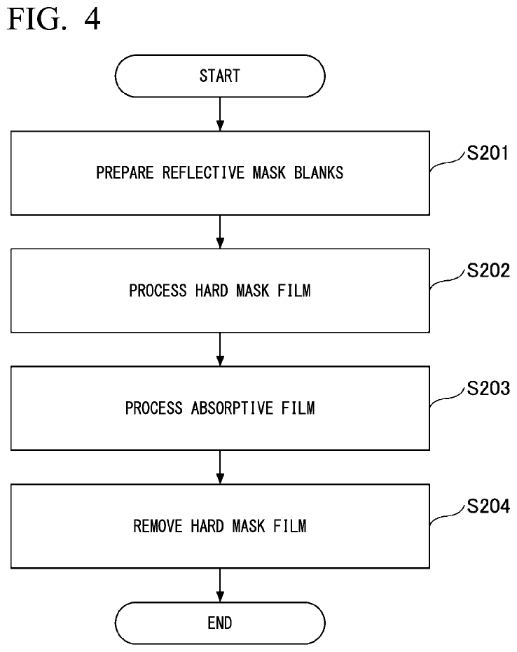

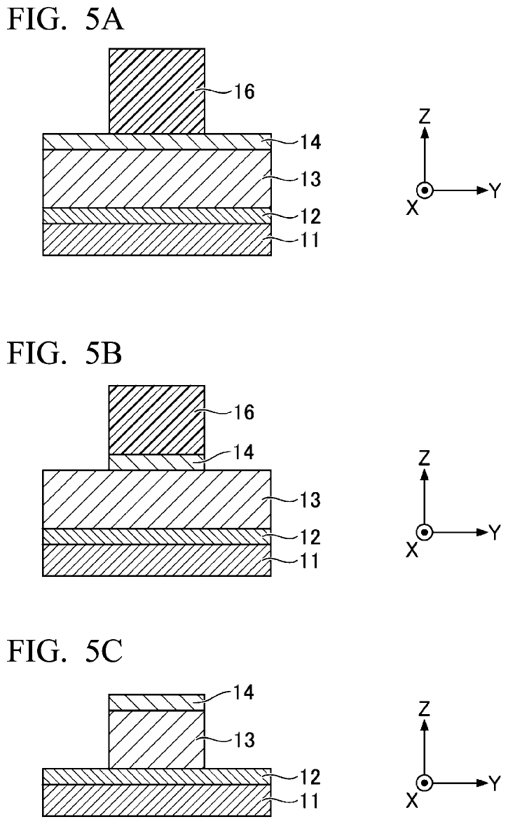

Next, with reference to FIG. 4 to FIG. 5C, a manufacturing method of the reflective mask 2 according to one embodiment will be described. The manufacturing method of the reflective mask 2 includes steps S201 to S204 shown in FIG. 4. In step S201, the reflective mask blank 1 is prepared, as shown in FIG. 5A. As shown in FIG. 5A, the reflective mask blank 1 includes a resist film 16. The resist film 16 is formed on the hard mask film 14. An opening pattern to be transferred to the absorbing film 13 is formed in the resist film 16.

In step S202, as shown in FIG. 5B, the hard mask film 14 is processed using the resist film 16 having the opening pattern. The hard mask film 14 is exposed to a second etching gas through openings in the resist film 16, and the second etching gas etches the hard mask film 14. At the end of step S202, the resist film 16 remains. As a result, the opening pattern of the resist film 16 is transferred to the hard mask film 14.

The second etching gas is selected depending on a combination of materials of the resist film 16 and the hard mask film 14, and may include, but is not limited to, a fluorine-based gas, for example. The fluorine-based gas includes, for example, at least one selected from CF₄ gas, CHF₃ gas, C₂F₆ gas, C₃F₆ gas, C₄F₆ gas, C₄F₈ gas, CH₂F₂ gas, CH₃F gas, C₃F₈ gas, F₂ gas, SF₆ gas, and NF₃ gas. The second etching gas may include an active gas or an inert gas in addition to the fluorine-based gas. The active gas includes at least one selected from O₂ gas and O₃ gas. The inert gas includes at least one selected from N₂ gas, He gas, and Ar gas. The second etching gas is preferably plasma-activated.

In step S203, as shown in FIG. 5C, the absorbing film 13 is processed using the hard mask film 14 having the opening pattern. The absorbing film 13 is exposed to the first etching gas through openings in the hard mask film 14, and the first etching gas etches the absorbing film 13. The hard mask film 14 has higher resistance to the first etching gas than the absorbing film 13. At the end of step S203, the hard mask film 14 remains. As a result, the opening pattern of the hard mask film 14 is transferred to the absorbing film 13.

The first etching gas is selected depending on a combination of materials of the hard mask film 14 and the absorbing film 13, and may include, but is not limited to, a chlorine-based gas and an oxygen-based gas, for example. The chlorine-based gas may include, for example, at least one selected from Cl₂ gas, SiCl₄ gas, CHCl gas, CCl₄ gas, and BCl₃ gas. The oxygen-based gas may include, for example, at least one selected from O₂ gas and O₃ gas. In addition to the chlorine-based gas and the oxygen-based gas, the first etching gas may also include an inert gas. The inert gas includes at least one selected from N₂ gas, He gas, and Ar gas, for example. The first etching gas is preferably plasma-activated.

In step S204, although not shown, the hard mask film 14 is removed. For example, a third etching gas is used to remove the hard mask film 14. Like the second etching gas, the third etching gas includes, for example, a fluorine-based gas. The third etching gas is preferably plasma-activated. A chemical solution may be used to remove the hard mask film 14.

Next, referring again to FIG. 1, the substrate 10, the multilayer reflective film 11, the protective film 12, the absorbing film 13, the hard mask film 14, and the conductive film 15 will be described in this order.

The substrate 10 is, for example, a glass substrate. A material of the substrate 10 is preferably quartz glass containing TiO₂. As compared to common soda-lime glass, quartz glass has a smaller linear expansion coefficient and experiences less dimensional change due to temperature changes. Quartz glass may contain 80 mass % to 95 mass % of SiO₂ and 4 mass % to 17 mass % of TiO₂. If the TiO₂ content is 4 mass % to 17 mass %, the linear expansion coefficient is nearly zero near room temperature, and there is almost no dimensional change near room temperature. Quartz glass may contain a third component or impurities other than SiO₂ and TiO₂. Also, the material of the substrate 10 may be crystallized glass in which a β-quartz solid solution is precipitated, silicon, metal, or the like.

The substrate 10 has the first major surface 10a and the second major surface 10b facing opposite to the first major surface 10a. The multilayer reflective film 11 and other elements are formed on the first major surface 10a. A size of the substrate 10 in a plan view (viewed in the Z axis direction) is, for example, 152 mm long and 152 mm wide. The longitudinal and lateral dimensions may be 152 mm or greater. The first major surface 10a and the second major surface 10b each have, for example, a square quality assurance region in a center. A size of the quality assurance region is, for example, 142 mm long and 142 mm wide. The longitudinal and lateral dimensions may be 142 mm or greater. The quality assurance region of the first major surface 10a preferably has a root-mean-square roughness (Rq) of 0.15 nm or less and a flatness of 100 nm or less. Also, the quality assurance region of the first major surface 10a preferably does not have any defects that cause phase defects.

The multilayer reflective film 11 reflects EUV light. The multilayer reflective film 11 is formed by alternately laminating high-refractive-index layers and low-refractive-index layers, for example. A material of the high-refractive-index layers is, for example, silicon (Si), a material of the low-refractive-index layers is, for example, molybdenum (Mo), and a Mo/Si multilayer reflective film is used. Also, a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo/Ru multilayer reflective film, a Si/Ru/Mo multilayer reflective film, and other films can also be used as the multilayer reflective film 11.

A film thickness of each layer forming the multilayer reflective film 11 and the number of repeat units of the layers can be selected appropriately depending on the material of each layer and the reflectivity for EUV light. If the multilayer reflective film 11 is a Mo/Si multilayer reflective film, in order to achieve a reflectivity of 60% or more for EUV light at an incident angle θ of 6° (see FIG. 6), Mo layers with a film thickness of 2.3±0.1 nm and Si layers with a thickness of 4.5±0.1 nm can be laminated so that the number of repeat units is 30 or more and 60 or less. The multilayer reflective film 11 preferably has a reflectivity of 60% or more for EUV light at an incident angle θ of 6°.

The reflectivity is more preferably 65% or more.

A deposition method for the layers forming the multilayer reflective film 11 is, for example, DC sputtering, magnetron sputtering, ion beam sputtering, or the like. In the case of forming a Mo/Si multilayer reflective film using ion beam sputtering, an example of deposition conditions for Mo layers and Si layers is as follows.

### <Deposition Conditions for Si Layers>

Target: Si target,
Sputtering gas: Ar gas,
Gas pressure: 1.3×10⁻² Pa to 2.7×10⁻² Pa,
Ion acceleration voltage: 300 V to 1500 V,
Deposition rate: 0.030 nm/sec to 0.300 nm/sec,
Si layer film thickness: 4.5±0.1 nm,

### <Deposition Conditions for Mo Layers>

Target: Mo target,
Sputtering gas: Ar gas,
Gas pressure: 1.3×10⁻² Pa to 2.7×10⁻² Pa,
Ion acceleration voltage: 300 V to 1500 V,
Deposition rate: 0.030 nm/sec to 0.300 nm/sec,
Mo layer film thickness: 2.3=0.1 nm,
   <Repeat units of Si Layers and Mo Layers>
Number of repeat units: 30 to 60 (Preferably 40 to 50).

The protective film 12 is formed between the multilayer reflective film 11 and the absorbing film 13 and protects the multilayer reflective film 11. The protective film 12 protects the multilayer reflective film 11 from the first etching gas when the absorbing film 13 is processed, that is, in step S203. The protective film 12 is not removed even when exposed to the first etching gas, but remains on the multilayer reflective film 11.

The protective film 12 contains, for example, at least one element selected from Ru, Rh, and Si. When the protective film 12 contains Rh, it may contain only Rh, or it may contain an Rh compound. The Rh compound may contain, in addition to Rh, at least one element selected from the group consisting of Ru, Nb, Mo, Ta, Ir, Pd, Zr, Y, and Ti.

The Rh compound may contain, in addition to Rh, at least one element selected from the group consisting of N, O, C, and B. While these elements reduce the resistance of the protective film 12 to the first etching gas, they reduce the crystallinity of the protective film 12, thereby improving the smoothness of the protective film 12. If the Rh compound has an amorphous or microcrystalline structure, the X-ray diffraction profile of the Rh compound will not have a clear peak.

In the present embodiment, the protective film 12 is a single layer film configured of a single layer, but it may be a multilayer film having a lower layer and an upper layer. The lower layer of the protective film 12 is a layer formed in contact with an uppermost surface of the multilayer reflective film 11. The upper layer of the protective film 12 is in contact with a lowermost surface of the absorbing film 13. In this way, by using a multilayer structure for the protective film 12, materials with excellent predetermined functions can be used for each layer, and thus the protective film 12 as a whole can be made multifunctional.

The upper layer of the protective film 12 preferably contains at least one element selected from Ru and Rh, more preferably contains Rh, and even more preferably contains a Rh compound. The lower layer of the protective film 12 preferably contains at least one element selected from Ru, Rh, Nb, Mo, Zr, Y, and Si, and more preferably Ru. Further, in order to suppress the crystallinity of the protective film 12, the lower layer of the protective film 12 preferably further contains, in addition to at least one of the above elements, at least one element selected from C, N, and B. If the protective film 12 is a multilayer film, a thickness of the protective film 12 below indicates a total film thickness of the multilayer film. Also, a mixing layer formed by mixing components contained in the multilayer reflective film 11 and components contained in the lower layer of the protective film 12 may be formed between the multilayer reflective film 11 and the lower layer of the protective film 12.

The thickness of the protective film 12 is preferably 1.0 nm to 4.0 nm, more preferably 2.0 nm to 3.5 nm, and even more preferably 2.5 nm to 3.0 nm. If the thickness of the protective film 12 is 1.0 nm or more, good etching resistance is achieved. In addition, if the thickness of the protective film 12 is 4.0 nm or less, good reflectivity for EUV light is achieved.

A density of the protective film 12 is preferably 10.0 g/cm³ to 14.0 g/cm³. If the density of the protective film 12 is 10.0 g/cm³ or more, good etching resistance is achieved. In addition, if the density of the protective film 12 is 14.0 g/cm³ or less, a decrease in reflectivity for EUV light can be suppressed.

A deposition method for the protective film 12 is, for example, DC sputtering, magnetron sputtering, ion beam sputtering, or the like. In the case of forming an Rh film using DC sputtering, deposition conditions are as follows.

### <Deposition Conditions for Rh Film>

Target: Rh target,
Sputtering gas: Ar gas,
Gas pressure: 1.0×10⁻² Pa to 1.0×10° Pa,
Target power density: 1.0 W/cm² to 8.5 W/cm²,
Deposition rate: 0.020 nm/sec to 1.000 nm/sec,
Film thickness: 1 nm to 10 nm.

The absorbing film 13 absorbs EUV light. The absorbing film 13 is a film in which the opening pattern 13op is to be formed. The opening pattern 13op is not formed during the manufacturing process of the reflective mask blank 1, but is formed during the manufacturing process of the reflective mask 2. The absorbing film 13 may not only absorb EUV light, but also shift a phase of the EUV light. That is, the absorbing film 13 may be a phase shift film. The phase shift film shifts a phase of second EUV light L2 relative to first EUV light L1 shown in FIG. 6.

The first EUV light L1 is light that passes through the opening pattern 13op of the absorbing film 13 without being absorbed by the absorbing film 13, is reflected by the multilayer reflective film 11, and passes through the opening pattern 13op of the absorbing film 13 without being absorbed again by the absorbing film 13. The second EUV light L2 is light that is absorbed by the absorbing film 13 while transmitting through the absorbing film 13, is reflected by the multilayer reflective film 11, and is again absorbed by the absorbing film 13 while transmitting through the absorbing film 13.

A phase difference (>0) between the first EUV light L1 and the second EUV light L2 is, for example, 170 degrees to 250 degrees. A phase of the first EUV light L1 may be ahead or behind a phase of the second EUV light L2. The absorbing film 13 utilizes the interference between the first EUV light L1 and the second EUV light L2 to improve a contrast of a transferred image. The transferred image is an image of the opening pattern 13op of the absorbing film 13 transferred onto a target substrate.

In EUVL, a so-called projection effect (shadowing effect) occurs. The shadowing effect indicates occurrence of regions near sidewalls of the opening pattern 13op that block EUV light due to an EUV light incident angle θ being non-zero (for example, 6 degrees), resulting in a positional deviation or dimensional deviation of the transferred image. To reduce the shadowing effect, it is effective to reduce a height of the sidewalls of the opening pattern 13op, and to thin the absorbing film 13.

To reduce the shadowing effect, a film thickness of the absorbing film 13 is, for example, 60 nm or less, and preferably 50 nm or less. To ensure the phase difference between the first EUV light L1 and the second EUV light L2, the film thickness of the absorbing film 13 is preferably 20 nm or more, and more preferably 30 nm or more.

To reduce the film thickness of the absorbing film 13 in order to reduce the shadowing effect while maintaining the phase difference between the first EUV light L1 and the second EUV light L2, it is effective to reduce a refractive index n of the absorbing film 13. In addition, to reduce the reflectivity for the second EUV light L2, it is effective to increase an extinction coefficient k of the absorbing film 13. As described above, the absorbing film 13 is required to have excellent optical properties.

The absorbing film 13 preferably contains at least one metal element selected from Cr, Ta, Nb, Ir, Pt, Pd, Os, Re, Au, and Ru. Since these metal elements have a relatively small refractive index, the film thickness of the absorbing film 13 can be reduced while maintaining the phase difference. The absorbing film 13 preferably contains a compound of a metal element. The compound of a metal element preferably contains at least one element selected from O, B, C, and N. By adding at least one element selected from O, B, C, and N, crystallization can be suppressed while suppressing degradation of optical properties, and the roughness of the opening pattern 13op can be reduced.

In the present embodiment, the absorbing film 13 is a single layer film configured of a single layer, but it may be a multilayer film having a lower layer and an upper layer. The lower and upper layers forming the absorbing film 13 are formed in this order on the protective film 12. An uppermost layer of the absorbing film 13 is a layer farthest from the protective film 12. The uppermost layer of the absorbing film 13 preferably contains at least one metal element selected from Cr, Ta, Nb, Ir, Pt, Pd, Os, Re, Au, and Ru, and more preferably contains a compound of a metal element. If the absorbing film 13 is a multilayer film, the thickness of the absorbing film 13 indicates a total film thickness of the multilayer film.

A deposition method for the absorbing film 13 is, for example, DC sputtering, magnetron sputtering, ion beam sputtering, or the like. A nitrogen content of the absorbing film 13 can be controlled by adjusting an N₂ gas content in a sputtering gas. In the case of forming a TaN film using reactive sputtering, an example of the deposition conditions is as follows.

### <Deposition Conditions for TaN Film>

Target: Ta target
Power density of Ta target: 1.0 W/cm² to 8.5 W/cm²
Sputtering gas: Mixture of Ar gas and N₂ gas
Volume ratio of N₂ gas in sputtering gas (N₂/(Ar+N₂)): 0.01 to 0.25
Gas pressure: 1.0×10⁻² Pa to 1.0×10⁰ Pa
Deposition rate: 0.020 nm/sec to 0.060 nm/sec
Film thickness: 20 nm to 60 nm

The hard mask film 14 is formed on a side opposite to the protective film 12 from the absorbing film 13 as a reference, and is used to form the opening pattern 13op in the absorbing film 13. The hard mask film 14 enables thinning of the resist film 16.

The hard mask film 14 preferably contains at least one metal element or metalloid element selected from Al, Hf, Y, Cr, Nb, Ti, Mo, Ta, and Si. The hard mask film 14 preferably contains a compound of the above metal element or metalloid element. The compound preferably contains at least one element selected from O, N, C, and B.

A thickness of the hard mask film 14 is preferably 2 nm to 30 nm, more preferably 2 nm to 25 nm, and even more preferably 2 nm to 10 nm.

A deposition method for the hard mask film 14 is, for example, DC sputtering, magnetron sputtering, ion beam sputtering, or the like.

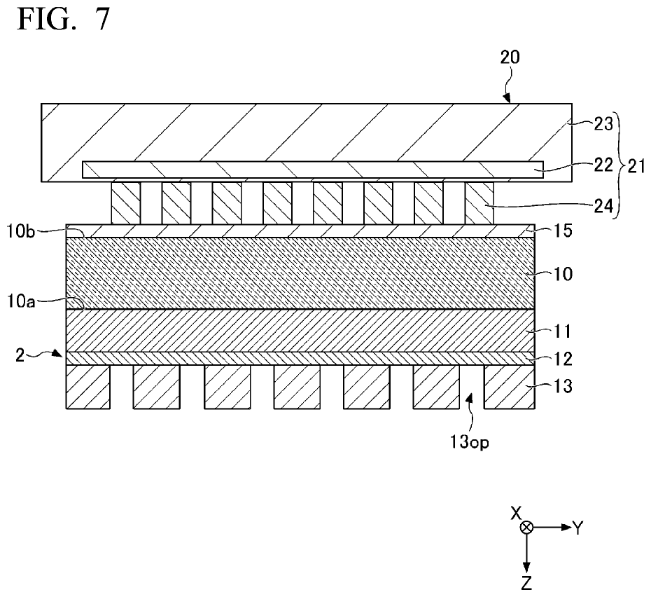

As shown in FIG. 7, the conductive film 15 is formed on a side opposite to the multilayer reflective film 11 from the substrate 10 as a reference, and is used to attach the reflective mask 2 to an electrostatic chuck 21 of an exposure device 20. The electrostatic chuck 21 has an electrode 22 that generates an electrostatic attraction force, an insulating stage 23 in which the electrode 22 is embedded, and a plurality of insulating burls 24 protruding from the stage 23. The plurality of burls 24 come into contact with the conductive film 15. In the present embodiment, each of the plurality of burls 24 is cylindrical, but they may be tapered cones.

The electrostatic chuck 21 repeatedly attaches and releases the reflective mask 2 for purposes such as maintenance, replacement, or the like of the reflective mask 2. In this case, to prevent the burls 24 of the electrostatic chuck 21 from wearing, the conductive film 15 preferably has a Young's modulus of 250 GPa or less as measured with a nanoindenter.

The nanoindenter performs a quasi-static indentation test on a sample to acquire mechanical properties of the sample. The nanoindenter is not particularly limited, and may be, for example, iMicro manufactured by KLA Corporation. The Young's modulus is calculated using, for example, a continuous stiffness measurement (CSM) method. To eliminate the influence of the substrate 10 as much as possible, a value of the Young's modulus at an indentation depth corresponding to one-third of a film thickness of the conductive film 15 is used.

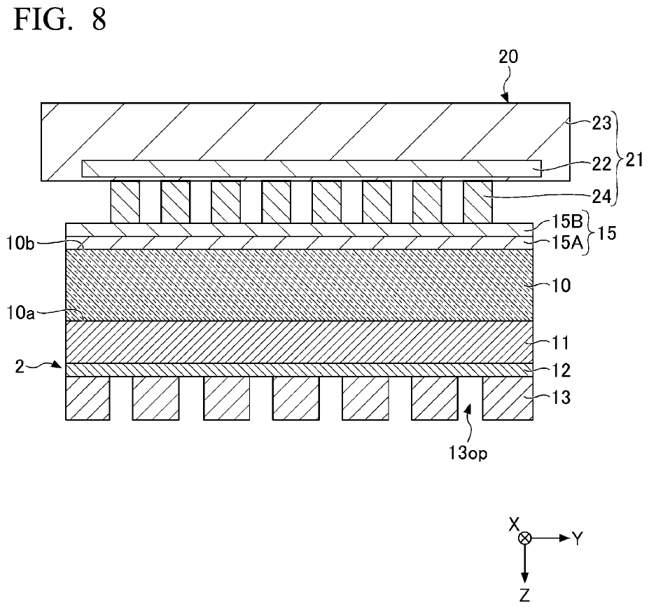

In the present embodiment, the conductive film 15 is a single layer film configured of a single layer, but it may be a multilayer film having a lower layer 15A and an upper layer 15B, as shown in FIG. 8. The lower layer 15A and the upper layer 15B forming the conductive film 15 are formed in this order on the substrate 10. The lower layer 15A is in contact with the substrate 10. The upper layer 15B is in contact with the plurality of burls 24.

Also, the lower layer 15A of the conductive film 15 does not have to be in contact with the substrate 10, and another functional film may be formed between the conductive film 15 and the substrate 10. The conductive film 15 may have an intermediate layer between the lower layer 15A and the upper layer 15B.

If the conductive film 15 is a multilayer film, the Young's modulus of the conductive film 15 is measured with the nanoindenter after all layers forming the conductive film 15 have been formed on the substrate 10. Even if the conductive film 15 is a multilayer film, the Young's modulus when the indentation depth is one-third of the film thickness of the conductive film 15 is used to eliminate the influence of the substrate 10 as much as possible.

If the Young's modulus of the conductive film 15 measured with the nanoindenter is 250 GPa or less, the conductive film 15 is sufficiently soft. Therefore, wear of the burls 24 of the electrostatic chuck 21 can be suppressed, thereby suppressing the generation of particles. Particles are caught between the electrostatic chuck 21 and the reflective mask 2, deforming the reflective mask 2. As a result, EUVL transfer accuracy may deteriorate. According to the present embodiment, the generation of particles can be suppressed, and the EUVL transfer accuracy can be improved.

The Young's modulus of the conductive film 15 measured with the nanoindenter is preferably 250 GPa or less, more preferably 220 GPa or less, and even more preferably 200 GPa or less. In addition, the Young's modulus of the conductive film 15 measured with the nanoindenter is preferably 100 GPa or more, and more preferably 120 GPa or more.

If the conductive film 15 is a single layer film, from the viewpoints of conductivity and stability, the conductive film 15 preferably contains at least one metal element selected from Cr and Ta. The conductive film 15 preferably contains a compound of the above metal element. The compound preferably contains at least one non-metal element selected from N, O, C, B, and Si. A total content of N, O, C, B, and Si in the compound is preferably 30 at % or less.

A value obtained by performing analysis using X-ray photoelectron spectroscopy (XPS) is used for the content of each element in the conductive film 15. Details of the content analysis method follow the method described in the examples below. If the conductive film 15 has a multilayer structure, analysis is performed while etching the conductive film 15 from a surface on a side opposite to the substrate 10 using, for example, argon ion sputtering, to analyze the content of each element in each layer of the conductive film 15.

If the conductive film 15 is a single layer film containing Ta and N, the Ta content is preferably 70 at % or more, and more preferably 75 at % or more. In addition, the Ta content is preferably 95 at % or less, more preferably 90 at % or less, and even more preferably 85 at % or less.

If the conductive film 15 is a single layer film containing Ta and B, the Ta content is preferably 70 at % or more, more preferably 75 at % or more, and even more preferably 80 at % or more. In addition, the Ta content is preferably 95 at % or less, more preferably 90 at % or less, and even more preferably 85 at % or less.

If the conductive film 15 is a single layer film containing Ta and B, the B content is preferably 5 at % or more, more preferably 10 at % or more, and even more preferably 15 at % or more. In addition, the B content is preferably 30 at % or less, more preferably 25 at % or less, and even more preferably 20 at % or less.

If the conductive film 15 is a multilayer film, the lower layer 15A preferably contains at least one metal element selected from Cr and Ta, from the viewpoints of conductivity and stability. The lower layer 15A preferably contains a compound of the above metal element. From the viewpoints of conductivity and film stress adjustment, the compound preferably contains at least one non-metal element selected from N, C, B, and Si. Among these non-metal elements, N is most preferable from the viewpoint of film stress adjustment. Adjusting the film stress can reduce warpage of the reflective mask 2. From the viewpoint of conductivity, the lower layer 15A preferably contains substantially no O. The O content of the lower layer 15A is preferably 0.1 at % or less.

If the conductive film 15 is a multilayer film and the lower layer 15A contains Ta and N, the Ta content is preferably 60 at % or more, more preferably 65 at % or more, and even more preferably 70 at % or more. In addition, the Ta content is preferably 95 at % or less, more preferably 90 at % or less, even more preferably 85 at % or less, and particularly preferably 80 at % or less.

If the conductive film 15 is a multilayer film and the lower layer 15A contains Ta and N, the N content is preferably 5 at % or more, more preferably 10 at % or more, even more preferably 15 at % or more, and particularly preferably 20 at % or more. In addition, the N content is preferably 40 at % or less, more preferably 35 at % or less, and even more preferably 30 at % or less.

If the conductive film 15 is a multilayer film and the lower layer 15A contains Cr and N, the Cr content is preferably 75 at % or more, more preferably 80 at % or more, and even more preferably 85 at % or more. In addition, the Cr content is preferably 95 at % or less, and more preferably 93 at % or less.

If the conductive film 15 is a multilayer film and the lower layer 15A contains Cr and N, the N content is preferably 3 at % or more, more preferably 5 at % or more, and even more preferably 7 at % or more. In addition, the N content is preferably 25 at % or less, more preferably 20 at % or less, even more preferably 15 at % or less, and particularly preferably 10 at % or less.

If the conductive film 15 is a multilayer film, the upper layer 15B is preferably made of a material softer than the lower layer 15A, and to reduce its hardness, preferably contains at least one non-metal element selected from O, B, Si, and C in a total content of 5 at % or more. Among these non-metal elements, O is most preferred from the viewpoint of chemical stability. A total content of the above non-metal elements is preferably 5 at % or more, more preferably 10 at % or more, and even more preferably 20 at % or more. The total content of the above non-metal elements is preferably 60 at % or less, and more preferably 55 at % or less. From the viewpoint of softness, the upper layer 15B preferably contains substantially no N. The N content of upper layer 15B is preferably 0.1 at % or less.

If the conductive film 15 is a multilayer film and the upper layer 15B contains Ta and O, the Ta content is preferably 45 at % or more, more preferably 50 at % or more, and even more preferably 55 at % or more. In addition, the Ta content is preferably 80 at % or less, more preferably 75 at % or less, even more preferably 70 at % or less, and particularly preferably 65 at % or less.

If the conductive film 15 is a multilayer film and the upper layer 15B contains Ta and O, the O content is preferably 20 at % or more, more preferably 25 at % or more, even more preferably 30 at % or more, and even more preferably 35 at % or more. In addition, the O content is preferably 55 at % or less, more preferably 50 at % or less, and even more preferably 45 at % or less.

If the conductive film 15 is a multilayer film and the upper layer 15B contains Cr and O, the Cr content is preferably 65 at % or more, more preferably 70 at % or more, and even more preferably 75 at % or more. In addition, the Cr content is preferably 95 at % or less, more preferably 90 at % or less, and even more preferably 85 at % or less.

If the conductive film 15 is a multilayer film and the upper layer 15B contains Cr and O, the O content is preferably 5 at % or more, more preferably 10 at % or more, and even more preferably 15 at % or more. In addition, the O content is preferably 35 at % or less, more preferably 30 at % or less, and even more preferably 25 at % or less.

If the conductive film 15 is a multilayer film, the upper layer 15B preferably contains at least one metal element selected from Cr and Ta, from the viewpoint of adhesion between the upper layer 15B and the lower layer 15A. The upper layer 15B and the lower layer 15A preferably contain the same metal element. For example, both the upper layer 15B and the lower layer 15A more preferably contain Cr. Alternatively, both the upper layer 15B and the lower layer 15A more preferably contain Ta. Both the upper layer 15B and the lower layer 15A may contain Cr and Ta.

If the conductive film 15 is a multilayer film, the upper layer 15B preferably has a thickness of 4 nm or more. As the upper layer 15B, which is softer than the lower layer 15A, becomes thicker, the wear of the burls 24 of the electrostatic chuck 21 can be reduced. The thickness of the upper layer 15B is preferably 4 nm or more, and more preferably 6 nm or more. However, the upper layer 15B has lower conductivity than the lower layer 15A. Thus, from the viewpoint of the conductivity of the conductive film 15, the thickness of the upper layer 15B is preferably 50 nm or less, and more preferably 30 nm or less.

A contact resistance of the conductive film 15 is preferably 1000×10⁻³ (2 cm² or less, more preferably 500×10⁻³ Ωcm² or less, and even more preferably 300×10⁻³ Ωcm² or less.

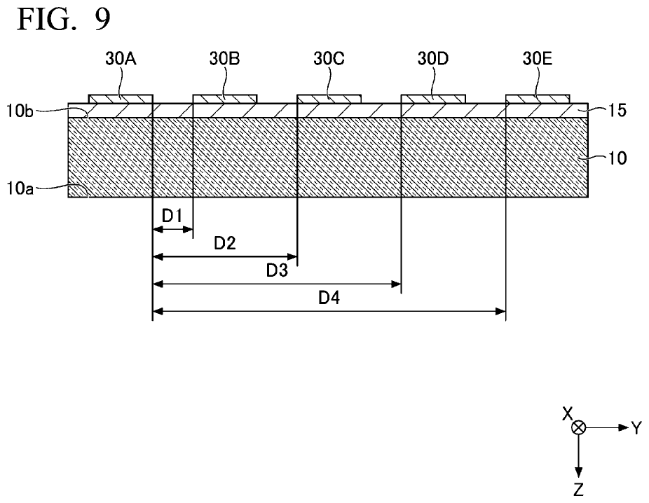

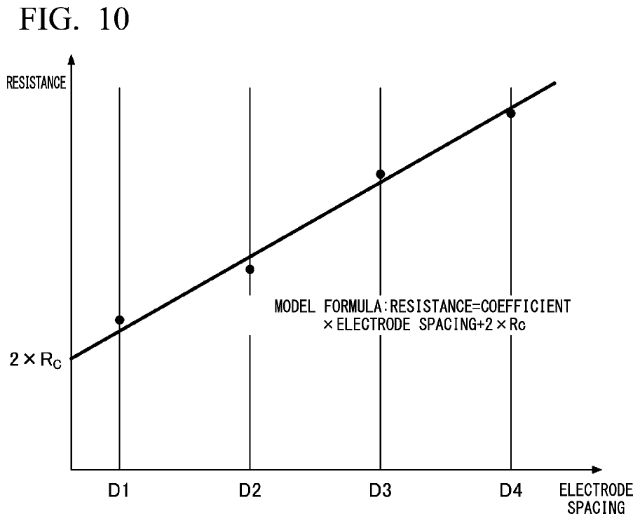

As shown in FIG. 9, the contact resistance of the conductive film 15 is determined by arranging five 1.2 mm diameter disk electrodes 30A, 30B, 30C, 30D, and 30E in a line at 2.0 mm intervals and measuring a resistance for each inter-electrode distance D1, D2, D3, and D4. D1 is 0.8 mm, D2 is 2.8 mm, D3 is 4.8 mm, and D4 is 6.8 mm. As shown in FIG. 10, the regression line is determined using the least squares method. A model formula for the regression line is shown in FIG. 10. The contact resistance (pc) can be obtained by dividing the intercept of the regression line (2×R_{C}) by 2 and multiplying it by the contact area(S) between one disk electrode and the conductive film 15 (ρ_{C}=R_{C}×S).

The thickness of the conductive film 15 is preferably 50 nm to 400 nm, and more preferably 70 nm to 350 nm. If the conductive film 15 is a multilayer film, the thickness of the conductive film 15 is the total thickness of the multilayer film.

A deposition method for the conductive film 15 is, for example, DC sputtering, magnetron sputtering, ion beam sputtering, or the like.

### EXAMPLES

Experimental data will be described below. In Examples 1 to 6, the conductive film 15 was formed on the substrate 10 under the deposition conditions shown in Table 1. Examples 1 to 3 are examples, and Examples 4 to 6 are comparative examples.

A SiO₂—TiO₂ glass substrate (outer shape: 6-inch (152 mm) square and 6.3 mm thick) was prepared as the substrate. This glass substrate had a thermal expansion coefficient at 20° C. of 0.02×10⁷/° C., a Young's modulus of 67 GPa, a Poisson's ratio of 0.17, and a specific rigidity of 3.07×10⁷ m²/s².

As shown in Table 1, in Example 1, a TaN film was deposited as the lower layer by magnetron sputtering, and a TaO film was subsequently deposited as the upper layer by magnetron sputtering. The deposition conditions for the TaN film and the TaO film were as follows:

### <Deposition Conditions for TaN Film>

Target: Ta target
Sputtering gas: Mixed gas containing 81 vol % Ar gas and 19 vol % N₂ gas
Gas pressure: 0.23 Pa
Input power density: 2.6 W/cm²

### <Deposition Conditions for TaO Film>

Target: Ta target
Sputtering gas: Mixed gas containing 40 vol % Ar gas by volume and 60 vol % 02 gas
Gas pressure: 0.05 Pa
Input Power density: 2.7 W/cm²

### (Conductive Film Composition)

A composition of the formed conductive film 15 was analyzed using XPS. A PHI 5000 VersaProbe manufactured by ULVAC-PHI, Inc. was used for XPS. The composition determined by analysis is shown in Table 1 below.

### (Film Thickness)

A film thickness of the conductive film 15 was measured using X-ray reflectivity (XRR). The XRR measurement was performed using SmartLab HTP manufactured by Rigaku Corporation. CuKα radiation was used as an X-ray source, with a tube voltage of 40 kV and a tube current of 30 mA. The accompanying software (GlobalFit) was used for analysis.

In Examples 2 to 6, the conductive film 15 was formed on the substrate 10 under the same conditions except that the deposition conditions were changed as shown in Table 1.

TABLE 1

| | | | Example | | Example | Example | | Example | Example | Example |
|---|---|---|---|---|---|---|---|---|---|---|
| | | | 1 | | 2 | 3 | | 4 | 5 | 6 |
| Layer structure | | | Multilayer | | Single | Multilayer | | Single | Single | Single |
| | | | Lower | Upper | layer | Lower | Upper | layer | layer | layer |
| | | | layer | layer | | layer | layer | | | |
| Film type | | | TaN | TaO | TaB | CrN | CrO | CrN | TaN | Tab |
| Film thickness | | | 70 | 10 | 350 | 360 | 20 | 360 | 350 | 350 |
| Deposition | Input power | Ta | 2.6 | 2.7 | 2.8 | — | — | — | 6.9 | — |
| conditions | density | Ta₃B₂ | — | — | 6.9 | — | — | — | — | 6.9 |
| | [W/cm²] | Cr | — | — | — | 4.6 | 4.1 | 4.6 | 1 | — |
| | Gas pressure [Pa] | | 0.23 | 0.05 | 0.21 | 0.1 | 0.1 | 0.1 | 0.13 | 0.12 |
| Content | | Ta | 71 | 60 | 82 | — | — | — | 81 | 77 |
| [at%] | | Cr | — | — | — | 91 | 80 | 91 | — | — |
| | | O | — | 40 | — | — | 20 | — | — | — |
| | | B | — | — | 18 | — | — | — | — | 23 |
| | | N | 29 | — | — | 9 | — | 9 | 19 | |

| | | | | | | |
|---|---|---|---|---|---|---|
| Young's modulus [GPa] | 161.4 | 179.5 | 247.6 | 258.7 | 261.5 | 252.1 |
| Evaluation of contamination | Good | Good | Good | Poor | Poor | Poor |

After the conductive film 15 was formed, contamination was evaluated using a wear resistance test. In Table 1, a contamination rating of “Good” indicates that no particles or scratches were found on the lens surface during the wear resistance test, while a contamination rating of “Poor” indicates that at least one of particles and scratches was found on the lens surface during the wear resistance test. In addition, the wear resistance test was conducted in a vacuum as follows. First, a lens (with a curvature 0.18 cm, made of a material BK-7) simulating the burls 24 was prepared. The lens had a TiN film on its surface. Next, the substrate 10 was placed on a vibration stage with the conductive film 15 facing upward. Next, the vibration stage was vibrated while the downward-facing lens and the conductive film 15 were in contact. Vibration conditions were a stroke of 0.1 mm, a frequency of 14 Hz, and a vibration time of 15 hours. After that, the lens surface was observed with an optical microscope for the presence or absence of particles and scratches, and wear resistance was evaluated.

Unlike Examples 4 to 6, in Examples 1 to 3, the Young's modulus of the conductive film 15 was 250 GPa or less, and thus no particles or scratches were observed on the lens surface during the wear resistance test. This shows that Examples 1 to 3 are able to suppress the wear of the burls 24 of the electrostatic chuck 21 and reduce particle generation compared to Examples 4 to 6.

In Example 1, a soft upper TaO film was formed on a hard lower layer (TaN film), and thus, unlike Example 5, the Young's modulus of the conductive film 15 was 250 GPa or less. In Example 3, a soft upper CrO film was formed on a hard lower layer (CrN film), and thus, unlike Example 4, the Young's modulus of the conductive film 15 was 250 GPa or less.

In Example 2, the gas pressure during deposition of the conductive film 15 was higher than in Example 6, and thus the Young's modulus of the conductive film 15 was 250 GPa or less. It was found that, even if the film type is the same, the Young's modulus of the conductive film 15 can be reduced to 250 GPa or less when the gas pressure during deposition is higher.

In the present examples, the dynamic friction coefficient and other parameters were evaluated for the substrate with the conductive film formed thereon, but the evaluation results for the dynamic friction coefficient and other parameters are also similar when the conductive film is formed as part of a reflective mask blank.

The reflective mask blank, the reflective mask, the reflective mask blank manufacturing method, and the reflective mask manufacturing method according to the present disclosure have been described above, but the present disclosure is not limited to the above-described embodiments. Various changes, modifications, substitutions, additions, deletions, and combinations are possible within categories described in the scope of the claims. All of these also naturally fall within the technical scope of the present disclosure.

This application claims priority based on Japanese Patent Application No. 2023-201163, filed with the Japan Patent Office on Nov. 29, 2023, and the entire contents of Japanese Patent Application No. 2023-201163 are incorporated herein by reference.

### REFERENCE SIGNS LIST

1 Reflective Mask Blank
2 Reflective Mask
10 Substrate
11 Multilayer Reflective Film
13 Absorbing film
15 Conductive Film

1. A reflective mask blank comprising a substrate, a multilayer reflective film configured to reflect EUV light, and an absorbing film configured to absorb EUV light, in this order, and further comprising a conductive film on a side opposite to the multilayer reflective film from the substrate as a reference,
wherein the conductive film has a Young's modulus of 250 GPa or less as measured with a nanoindenter.

2. The reflective mask blank according to claim 1,
wherein the conductive film has conductive lower and upper layers, the lower layer and the upper layer being formed in this order on the substrate,
the lower layer contains at least one metal element selected from Cr and Ta, and
the upper layer contains at least one non-metal element selected from O, B, Si, and C in a total amount of 5 at % or more.

3. The reflective mask blank according to claim 2, wherein the upper layer has a thickness of 4 nm or more.

4. The reflective mask blank according to claim 2, wherein the lower layer contains at least one non-metal element selected from N, B, Si, and C.

5. The reflective mask blank according to claim 2, wherein the upper layer contains at least one metal element selected from Cr and Ta.

6. The reflective mask blank according to claim 1, wherein the conductive film has a contact resistance of 1000×10⁻³ Ωcm² or less.

7. The reflective mask blank according to claim 1, wherein the conductive film has a film thickness of 50 nm to 400 nm.

8. A reflective mask comprising the reflective mask blank according to claim 1,
wherein the absorbing film includes an opening pattern.

9. A reflective mask blank manufacturing method comprising:
preparing a substrate having a first main surface and a second main surface facing opposite to the first main surface;
depositing a multilayer reflective film configured to reflect EUV light and an absorbing film configured to absorb EUV light on the first main surface of the substrate in this order; and
depositing a conductive film on the second main surface of the substrate,
wherein the conductive film has a Young's modulus of 250 GPa or less as measured with a nanoindenter.

10. A reflective mask manufacturing method comprising, in this order:
preparing the reflective mask blank according to claim 1; and
forming an opening pattern in the absorbing film.
